(19) United States
(12) Patent Application Publication
(10) Pub. No.: US 2026/0215168 A1
(43) Pub. Date: Jul. 23, 2026

(54) TRILAYER JOSEPHSON JUNCTION AND ASSOCIATED FABRICATION METHOD

(71) Applicant: THE UNIVERSITY OF CHICAGO, Chicago, IL (US)

(72) Inventors: David I. SCHUSTER, Stanford, CA (US); Kan-Heng LEE, Davis, CA (US); Alexander ANFEROV, Chicago, IL (US); Jonathon SIMON, Palo Alto, CA (US)

(21) Appl. No.: 19/120,483

(22) PCT Filed: Oct. 13, 2023
(86) PCT No.: PCT/US2023/035153

§ 371 Date: Apr. 11, 2025

Related U.S. Application Data
(60) Provisional application No. 63/379,490, filed on Oct. 14, 2022.

(51) Int. Cl. H10N 60/12; H10N 60/82

(52) U.S. Cl. CPC H10N 60/12; H10N 60/82

(57) ABSTRACT

A Josephson junction includes a substrate, a trilayer stack, and a wiring layer. The trilayer stack includes a base electrode located directly on a top face of the substrate, an internal layer located on top of the base electrode, a barrier layer located on top of the internal layer, and a counter electrode located on top of the barrier layer and fully covering the barrier layer. The wiring layer is electrically connected to the counter electrode and includes a top section located directly on top of the counter electrode, a bottom section located directly on the top face of the substrate and adjacent to the base electrode, and a middle section directly connecting between the top section and the bottom section such that the middle section forms a gap with the trilayer stack. No spacer material directly contacts the trilayer stack.

### RELATED APPLICATIONS

This application claims priority to U.S. Provisional Patent Application No. 63/379,490, filed on Oct. 14, 2022, which is incorporated herein by reference in its entirety.

### STATEMENT REGARDING FEDERALLY SPONSORED RESEARCH OR DEVELOPMENT

This invention was made with government support under grant number 5-64020 awarded by the Department of Energy. The government has certain rights in the invention.

### BACKGROUND

Superconducting Josephson junctions are formed by two superconductors separated by a thin barrier whose thickness is typically less than 2 nm. Superconducting Josephson junctions are used in a variety of applications, including superconducting quantum logic circuits, quantum sensing and metrology, quantum computation and information processing, and studies of emergent phenomena in quantum circuits.

### SUMMARY

While the original Josephson junction technologies were fabricated with relatively high-temperature superconducting materials, such as lead and niobium, the demonstration of low-loss aluminum-based Josephson junctions led to their widespread adoption for sensitive quantum circuitry, where it is crucial to minimize decoherence. However, due to their lower superconducting critical current, quantum circuits using aluminum-based Josephson junctions are still limited to operation at extremely low temperatures (e.g., less than 0.1 K) and low frequencies (e.g., less than 70 GHz).

To increase the frequencies and temperatures of quantum circuits, the present embodiments include niobium-based Josephson junctions with loss levels comparable to their aluminum counterparts. These Josephson junctions may be formed with higher critical temperature niobium as the primary superconductors, separated by an aluminum oxide barrier that is encapsulated on both sides by pure aluminum for chemical isolation. However, the techniques described herein could be extended to any superconducting material stack (e.g., NbN/AlN, TiN/MgO, etc.).

The trilayer stack is grown vertically on a clean substrate in vacuum to minimize contamination. The stack is patterned using plasma reactive ion etching (RIE) optimized to reduce contamination. To make superconducting contact to the top layer of the junction, we isotropically grow a silicon dielectric using chemical vapor deposition (CVD), then anisotropically remove this dielectric. The relative anisotropy difference in growth leaves behind ramps of the material near the edges of the patterned junction layer (see sidewall spacers 202 in FIG. 2A). Finally, we clean the surface in vacuum, deposit a second layer of primary superconductor (e.g., niobium), and pattern the top two exposed layers with plasma RIE, also optimized to reduce contamination.

The finished circuit undergoes a final chemical treatment to remove the remaining dielectric material and clean the metal surfaces. Specifically, we use a liquid etch and wet-chemical etch to completely remove the remaining silicon dielectric. Since the etch chemistry also reacts with aluminum, we use a commercial etchant optimized for aluminum selectivity and keep the etch time short enough to minimize damage to the aluminum forming the actual junction area. This reaction also typically has the benefit of removing a small amount of niobium oxide as well, which also helps to reduce loss.

To further reduce losses, the Josephson junction may be fabricated on an atomically-clean, low-loss substrate (e.g., annealed and etched sapphire). Low-density plasma RIE etches are used to minimize lossy carbon and fluorocarbon residues on metal walls. Quantum circuits made with these Josephson junctions show losses approaching those made with conventional aluminum Josephson junctions, paving the way for higher temperature and higher frequency superconducting quantum devices.

One improvement of the Josephson junction disclosed herein is the reduction of loss and decoherence. By using these junctions to fabricate a cooper-pair box in the transmon limit, we have measured losses approaching those of traditional aluminum junctions. In fact, the losses are lower than previously reported with any junction using a superconductor whose critical temperature is higher aluminum. We attribute this improvement to several factors. First, unlike the traditional Nb—Al—AlOₓ—Nb junction, we add a thin (<10 nm thick) aluminum layer on top of the oxidized first aluminum layer to chemically isolate the aluminum oxide from the niobium, thus forming a Nb—Al—AlOₓ—Al—Nb junction. Second, we utilize the self-aligned sidewall passivation spacer method to form a wiring layer with minimal dielectric material. This spacer method is used to make contact to the top layer of the Josephson junction without contacting the bottom layer. This dielectric material can be deposited using plasma chemical vapor deposition, known to form very high quality dielectrics. To further reduce decoherence and loss, we chemically remove the remaining spacer material (with minimal damage to the aluminum junction layer), leaving the wiring layer suspended.

The junction current density can be tuned by annealing the devices at elevated temperatures, either in vacuum or during the fabrication process. Effectively adjusting the barrier parameters this way allows the Josephson junction disclosed herein to target a much wider range of parameters than possible by controlling the device area.

### BRIEF DESCRIPTION OF THE FIGURES

FIG. 1 is a diagram of a trilayer Josephson junction, in accordance with some of the present embodiments.

FIG. 2A illustrates a method for fabricating the trilayer Josephson junction of FIG. 1, in accordance with some of the present embodiments.

FIG. 2B is an electron micrograph of a finished sample of the trilayer Josephson junction of FIG. 1, as fabricated using the method of FIG. 2A.

FIG. 3 shows measured properties of the trilayer Josephson junction of FIG. 1.

FIG. 4 shows measured properties of qubits made with the trilayer Josephson junction of FIG. 1.

FIG. 5 is a plot of qubit quality factors as a function of temperature.

FIG. 6 illustrates superconductor material quality.

FIG. 7 illustrates etch residue chemical analysis

FIG. 8 illustrates etch residue Nak reactivity.

FIG. 9 illustrates how properties of the Josephson junction of FIG. 1 depend on junction area.

FIG. 10 illustrates the effects of annealing on the performance of the Josephson junction of FIG. 1.

FIG. 11 is a schematic of a microwave measurement setup used for qubit characterization of the Josephson junction of FIG. 1.

FIG. 12 illustrates material loss of the Josephson junction of FIG. 1, as probed by resonator quality factor.

### DETAILED DESCRIPTION

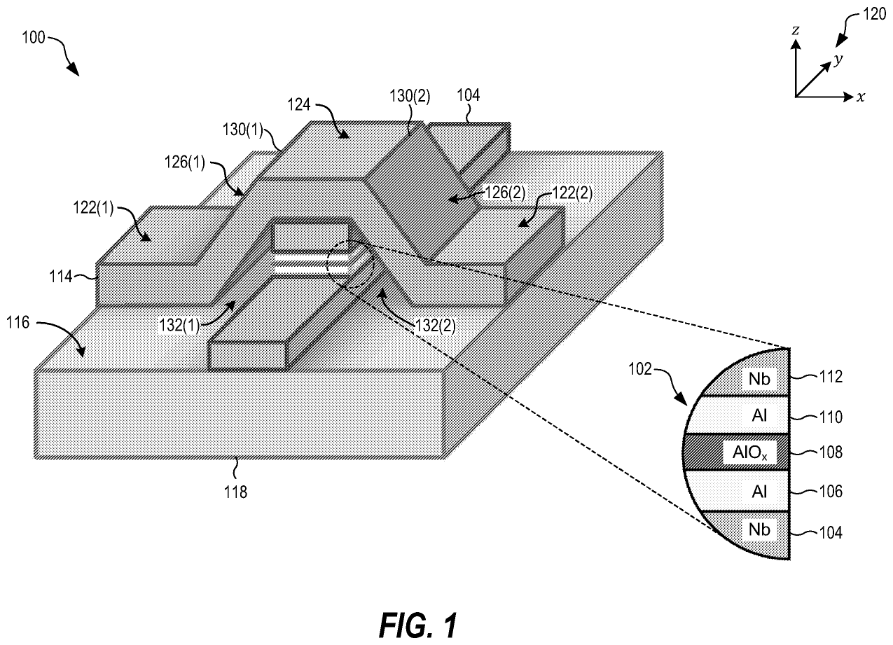

FIG. 1 is a diagram of a trilayer Josephson junction 100, in accordance with some of the present embodiments. The Josephson junction 100 includes a trilayer stack 102 that is formed on a top face 116 of a substrate 118. The substrate 118 lies flat in the x-y plane (see right-handed Cartesian coordinate system 120) such that the top face 116 points in the +z direction. The Josephson junction 100 includes a base electrode 104 that is located directly on the top face 116. Here, the term “directly” means that the base electrode 104 contacts the top face 116 without any intervening material, layer, or component. In the example of FIG. 1, the base electrode 104 is made from niobium. However, the base electrode 104 made be made of an alternative superconducting material, as described in more detail below.

The trilayer stack 102 also includes an internal layer 106 located on top (i.e., in the +z direction) of the base electrode 104, a barrier layer 108 located on top of the internal layer 106, and a counter electrode 112 located on top of the barrier layer 108. In FIG. 1, the trilayer stack 102 also includes a capping layer 110 located between the barrier layer 108 and the counter electrode 112. The capping layer 110 advantageously prevents oxygen in the barrier layer 108 from diffusing into the counter electrode 112, where it can form lossy materials (e.g., NbO₂) that reduce the coherence times of the Josephson junction 100. In some embodiments, and as shown in FIG. 1, the capping layer 110 fully covers the barrier layer 108 and the counter electrode 112 fully covers the capping layer 110. In some embodiments, the capping layer 110 has a thickness (along z) of 10 nm or less. However, the capping layer 110 may not needed for certain materials and therefore is excluded in some embodiments.

In FIG. 1, the base electrode 104 is shaped approximately as a right rectangular prism having a length (along y) that is greater than its width (along x). The internal layer 106, barrier layer 106, capping layer 110 (when included), and counter electrode 112 may have the same length, as shown in FIG. 1, or different lengths. This same length may be less than the length of the base electrode 104, as shown in FIG. 1. The base electrode 104, internal layer 106, barrier layer 108, capping layer 110, and counter electrode 112 may all have the same width, as shown in FIG. 1, or different widths. Each of the base electrode 104, internal layer 106, barrier layer 108, capping layer 110, and counter electrode 112 may have a different geometry than shown in FIG. 1 without departing from the scope hereof.

The Josephson junction also includes a step-like wiring layer 114 that is partially located over the trilayer stack 102 and is electrically connected to the counter electrode 112. The wiring layer 114 includes a first bottom section 122(1) that is located directly on the top face 116 of the substrate 118 and spaced apart from the base electrode 104 such that the first bottom section 122(1) and base electrode 104 are not electrically shorted to each other. The wiring layer 114 also includes a second bottom section 122(2) that is located directly on the top face 116 and spaced apart from the base electrode 104 such that the second bottom section 122(2) and base electrode 104 are not electrically shorted to each other. The bottom sections 122(1) and 122(2) are located on opposite sides (along x) of the base electrode 104. The wiring layer 114 also includes a top section 124 that is located directly on top of the counter electrode 112. The top section 124 may completely cover the counter electrode 112, as shown in FIG. 1.

The wiring layer 114 also includes a first middle section 126(1) that directly connects between the first bottom section 122(1) and a first edge 130(1) of the top section 124. The first middle section 126(1) forms a first gap 132(1) with the trilayer stack 102. The wiring layer 114 also includes a second middle section 126(2) that directly connects between the second bottom section 122(2) and a second edge 130(2) of the top section 124. The edges 130(1) and 130(2) are located on opposite sides of the top section 124. The second middle section 126(2) forms a second gap 132(2) with the trilayer stack 102. The gaps 132(1) and 132(2) are located on opposite sides of the trilayer stack 102. In one embodiment, the wiring layer 114 excludes the second middle section 126(2) and the second bottom section 122(2). In this embodiment, the second gap 132(2) is not formed.

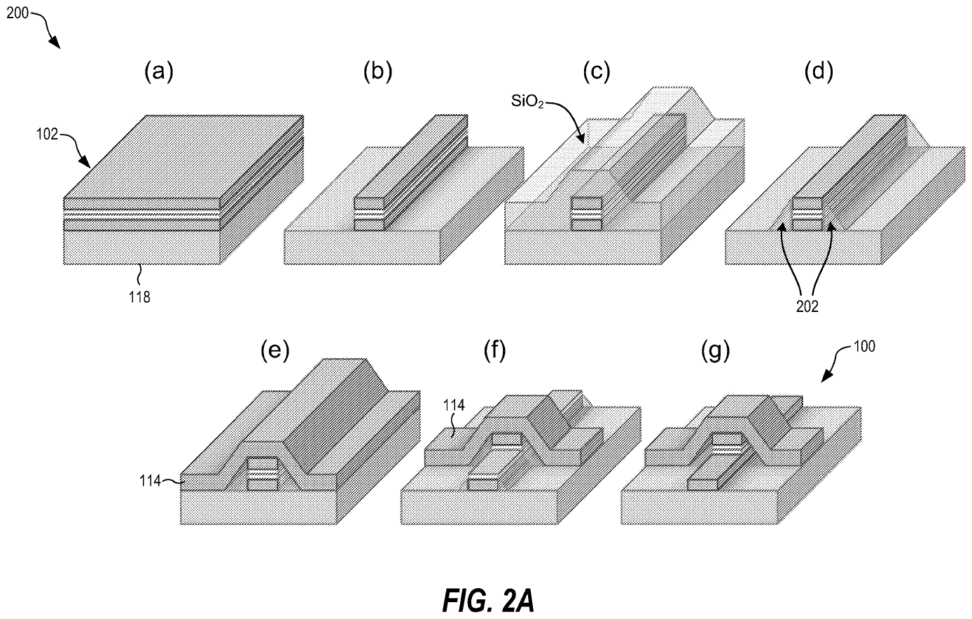

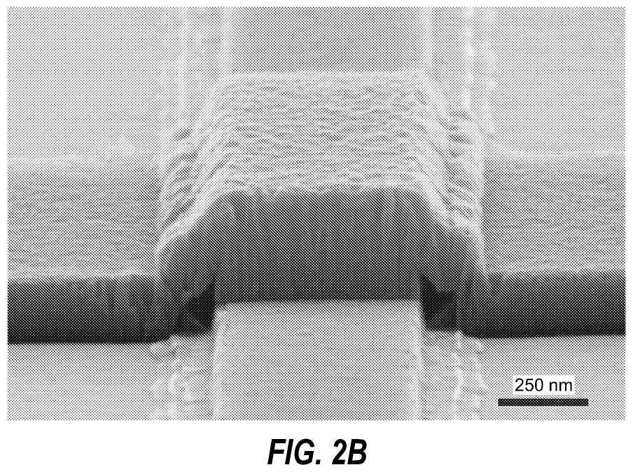

The Josephson junction 100 has no spacer material (e.g., dielectric material, such as SiO₂; also see spacers 202 in FIG. 2A) directly contacting the trilayer stack 102. Accordingly, the first gap 132(1) is completely devoid of any solid-state material between the first middle section 126(1) and a first side wall of the trilayer stack 102. Similarly, the second gap 132(2) is completely devoid of any solid-state material between the second middle section 126(2) and a second side wall of the trilayer stack 102. As described in more detail below, the removal of all spacer materials, including all dielectric material inside the gaps 132(1) and 132(2), increases the coherence times of the Josephson junction 100.

In the example of FIG. 1, the base electrode 104 and counter electrode 112 are both made from niobium (Nb), the internal layer 106 and capping layer 110 are both made from aluminum (Al), and the barrier layer 108 is made from aluminum oxide (AlOₓ). In general, the electrodes 104 and 112 may be made of any type of superconducting material while the layers 106, 108, and 110 may be made of a superconducting material, a normal metal, or an electrical insulator. In some embodiments, the base electrode 104 and counter electrode 112 are both fabricated from the same first type of superconducting material while the internal layer 106 is fabricated from a second type of superconducting material that is different from the first type of superconducting material. Examples of the first and second types of superconducting materials include, but are not limited to, niobium, niobium nitride, titanium nitride, and aluminum. The barrier layer 108 may be fabricated from an insulator (e.g., aluminum oxide, niobium oxide, aluminum nitride), a normal metal (e.g., titanium), or a superconducting material (e.g., aluminum). When the capping layer 110 is included, the internal layer 106 and capping layer 110 may both be the same material (e.g., aluminum). The substrate 118 may be sapphire or another material that is inert to the etching processing described below (see the method 200 in FIG. 2A). Examples of such materials that may alternatively be used for the substrate 118 include, but are not limited to, silicon (e.g., a crystalline silicon wafer), silicon carbide, silicon germanium, and silicon nitride.

### Demonstration

A wide variety of superconducting devices have been developed based on Josephson junctions. Their applications range from quantum-limited amplification and metrology [1-3] to digital logic [4-6] and they are an attractive platform for scalable quantum computing architectures due to their design flexibility and wide range of coupling strengths. Increasingly complex and robust quantum circuits have been demonstrated with aluminum junctions [7], however niobium is a tantalizing alternative superconductor due to its larger energy gap (and thus higher critical temperature and pair-breaking photon frequency) [8]. Taking advantage of this wider operating regime, niobium trilayer Josephson junctions became standard for single-flux quantum circuits operating at liquid helium temperatures [4-6]. Employing these well-established fabrication processes, some early implementations of superconducting qubits were developed with niobium junctions [9-16]. However, these initial niobium qubits only retained quantum state coherence for less than 400 ns, diminished by coupling to sources of dephasing and dissipation in the junction and the qubit environment.

Minimizing these loss sources is crucial in all sensitive quantum systems, but particularly for qubits, which must remain coherent over the duration of many gate operations. Significant effort has since been dedicated to investigating and reducing sources of decoherence [17], demanding either adjustments of circuit geometry to limit or dilute coupling to spurious channels or reducing the use of lossy amorphous dielectric materials. The need for insulated wiring contacts in these niobium trilayer junctions required growing passivating amorphous dielectric material in direct contact with the junction barrier, which likely degraded early qubit coherence [18] and limited their use in quantum devices. Higher temperature junctions with low loss promise a transformative source of strong nonlinearity for high-frequency quantum devices [19, 20] and have since seen renewed interest from efforts to integrate digital and quantum logic [21-23] and the exploration of tunnel barrier materials beyond the limitations of aluminum [24-26]. Notably, by removing amorphous insulating scaffolding and increasing the circuit volume to reduce junction participation, qubits with epitaxially grown NbN junctions with crystalline AlN barriers have increased coherence times to 16 μs [27]. We apply similar improvements to traditional Nb/Al/AlOₓ processes, which are attractive due to the simpler deposition methods required.

In this section, we use an improved fabrication method to revisit niobium trilayer junctions as the core component of transmon qubits and explore their coherence properties. We describe a method to form a temporary self-aligned sidewall-passivating spacer structure based on Ref. [28], which limits the amorphous spacer material to the smallest necessary region, and can later be chemically removed to further reduce dielectric loss. We find that high-temperature spacer growth methods greatly reduce the critical current density of the junction barrier, allowing us to utilize exclusively optical lithography to fabricate high-nonlinearity junctions for microwave qubits. We find that our all-niobium qubits have lifetimes as high as 62 μs with an average qubit quality factor of 2.57×10⁵, much closer to state-of-the-art qubits than past Nb/Al/AlOₓ devices [9-14]. We further observe that the higher superconducting gap energy results in reduced sensitivity to quasiparticles, particularly above 160 mK, where conventional aluminum-junction qubit performance deteriorates. These results demonstrate the reemergent relevance of niobium junctions for pushing the boundaries of superconducting devices.

Despite niobium's attractive electrical properties, in thin layers its oxides are imperfect insulators with high dielectric loss [18], resulting in very poor natural tunnel junction barriers. Aluminum, on the other hand, forms a thin self-terminating oxide with low leakage and loss, but has a low critical temperature. The trilayer method leverages the strengths of both of these materials by using a thin layer of oxidized aluminum as the tunnel barrier and encapsulating it with niobium. Through the proximity effect, the Josephson junction inherits desirable electrical properties and a clean tunnel barrier. This trilayer structure is typically grown on a wafer-scale as the first step in fabrication, enabling excellent uniformity [29, 30] and high-purity growth methods.

FIG. 2A illustrates a method 200 for fabricating the trilayer Josephson junction 100 of FIG. 1, in accordance with some of the present embodiments. Additional details about the method 200 are presented below in Appendix A. In step (a), the trilayer 102 is deposited on the substrate 118 and oxidized in-situ. In step (b), the layers are on the substrate 118 are etched with a chlorine reactive ion etch (RIE). In step (c), SiO₂ is grown isotropically. In step (d), sidewall spacers 202 are formed by anisotropic etching with fluorine chemistry. In step (e), surface oxides are cleaned in vacuum and the wiring layer 114 is deposited. In step (f), a second junction finger (and other circuit elements) are defined by a fluorine plasma etch selective against aluminum. In step (g), a wet etch is used to further remove SiO₂, exposed Al and some NbOₓ. FIG. 2B is an electron micrograph of a finished sample of the trilayer Josephson junction 100, as fabricated using the method 200 of FIG. 2A.

Similar to methods using sputtering, the trilayer stack 102 (also referred to simply as the “trilayer”) is formed in a shadow-evaporation-compatible electron-beam system by depositing 80 nm of Nb and 8 nm of Al on a high-purity, single-crystal, sapphire substrate 118 that has been annealed and chemically etched to remove surface damage. The deposition rate is kept high to maximize film quality (see Appendix B). To reduce defects and promote aluminum-oxide formation [31], the aluminum is first ion-milled and then oxidized with an O₂—Ar mixture. To prevent oxygen diffusion into the Nb counter electrode 112 and the formation of lossy NbOₓ [18, 32], the oxidized Al surface (i.e., the barrier layer 108) is protected by a thin (~3 nm) capping layer 110 of Al. The capping layer 110 is deposited while rotating the substrate 118 at an angle for complete coverage while keeping it thin enough to avoid affecting junction properties. A 150-nm-thick counter electrode 112 is then deposited on top, forming the trilayer 102 in-situ and without breaking vacuum.

The trilayer 102 is patterned with I-line [33] photolithography and plasma-etched in one step with Cl₂, BCl₃, and Ar to define the base electrode 104 (see step (b) in FIG. 2A). To make contact to the counter electrode 112 without touching the base electrode 104, we then form an insulating sidewall-passivating spacer structure [28]. Amorphous SiO₂ is grown isotropically (see step (c) in FIG. 2A) by either plasma-enhanced chemical vapor deposition (PECVD) which heats the wafer to 300° C. for 16 min or high-density plasma-enhanced chemical vapor deposition (HDPCVD) (90° C.). The SiO₂ is now etched anisotropically with a highly directional CF₄, CHF₃, and Ar plasma, which forms the spacer structure when the bulk material has been etched away (see step (d) in FIG. 2A). The contaminated trilayer surface is ion milled, and the 160-nm Nb wiring layer 114 is electron-beam-deposited on the sample (see step (e) in FIG. 2A). We verify that this forms a low-resistance contact to the counter electrode 112 (see Appendix B).

The wiring layer 114 is patterned and a selective SF₆, CHF₃, O₂, and Ar plasma etch removes the wiring layer 114 and the counter electrode 112, defining the perpendicular top junction electrode (see step (f) in FIG. 2A). This etch is carefully optimized to minimize the formation of lossy fluorocarbon polymers [34] (see Appendix C) while preserving chemical selectivity. Although the plasma etches the Al layers far slower than Nb, the etch is still timed to finish a few seconds after the counter electrode 112 is fully removed to limit excessive polymer deposition. Finally, to further remove the lossy amorphous materials present in the junction, a solution of NH₄F and acetic acid is used to dissolve the remaining SiO₂. This process additionally removes any exposed Al and a small amount of surface NbOₓ (see step (g) in FIG. 2A). As this step can dissolve Al in the junction as well, etch times are kept below 15 seconds. This final treatment could likely be improved with a HF vapor etch, which has shown good results forming similar contact structures [36].

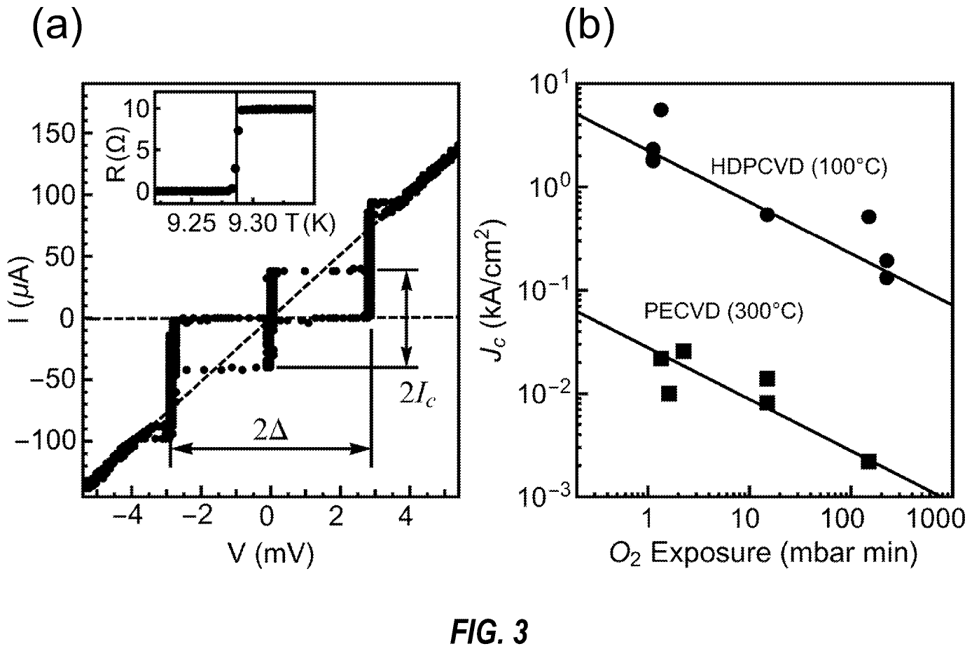

FIG. 3 shows measured properties of the trilayer Josephson junction 100 of FIG. 1. Panel (a) is a plot of current-voltage relations for an unshunted junction at 860 mK with I_{c}=38 μA and an energy gap of 6.6 meV, corresponding to critical temperature 9.2 K, in good agreement with resistivity measurements (see inset). Above 4 mV, a linear fit (dashed line) gives Rₙ=39Ω and a fit to the sub-gap region (dashed line) estimates sub-gap resistance Rₛ>8 kΩ. Panel (b) is a plot of the critical current density J_{c} (found by fitting room-temperature junction resistance as a function of junction area) as a function of oxygen exposure E measured for various wafers made with two deposition processes. The expected empirical E^{-1/2} relationships are plotted as guides to the eye.

We verify the expected Josephson junction behavior in our devices by measuring their hysteretic current-voltage curves, as shown in FIG. 3, panel (a). When cooled to 860 mK, the unshunted junction shows a zero-resistance superconducting branch up to the critical current I_{c}, and an energy gap 2Δ=5.64 meV, corresponding to a critical temperature T_{c}=9.2 K, in agreement with the transition temperature seen in resistivity measurements. Measuring the asymptotic normal state resistance Rₙ above the energy gap we find a I_{c}Rₙ product of 1.5 mV, similar to values reported previously for Nb trilayer junctions [28-30, 38, 39]. Although measurements of the subgap region were limited by the experiment hardware, no excessive subgap leakage currents were observed.

Using the I_{c}Rₙ product found above, we can use room-temperature junction resistances to predict low-temperature properties [40, 41]. Fitting the measured resistance for junctions of varying areas with two free parameters-specific resistivity and junction critical dimension bias (see Appendix D) —we obtain the effective junction areas and the specific critical current density J_{c} for each wafer. This method allows us to easily investigate effects of the fabrication process on junction electrical parameters. For Nb trilayers, the critical current density is sensitive to temperature [38] as well as oxygen exposure E, the product of oxygen partial pressure and oxidation time: this relationship has been empirically found to match J_{c}∝E^{-0.5} [28, 38, 42-44]. In FIG. 3, panel (b) is a plot of J_{c} as a function of E for wafers with trilayers grown using various oxidation parameters and fabricated with two spacer deposition methods. For the HDPCVD junctions, we find critical current densities in the kA cm⁻² range, comparable with other methods [28, 38, 39, 45], and observe reasonable agreement with the oxygen exposure dependence described above. The effect of process temperature is readily apparent when we examine junctions with high-temperature-grown PECVD spacers: compared to HDPCVD junctions, we observe nearly a factor of 50 reduction in J_{c}. We find this temperature-annealing effect activates above 200° C. (see Appendix E), in agreement with [38], and is likely the result of reduced barrier transparency from diffusion.

With access to wide ranges of J_{c}, we can use PECVD-annealed junctions to realize qubit junctions with optical lithography. We fabricate microwave transmon qubits [47, 48] with a standard geometry (see Appendix F) capacitively coupled to a coplanar waveguide resonator for dispersive readout. The qubit capacitor, ground plane, and readout resonator are defined on either the base electrode 104 or wiring layer 114, so no additional fabrication steps are needed. Chips with several qubits and their readout resonators sharing a common microwave feedline are characterized at the base stage of a dilution refrigerator (45-95 mK). Using microwave spectroscopy [47], we verified that our qubits have anharmonicities around 140 MHz, and couple with strengths of 30-60 MHz to their readout resonators.

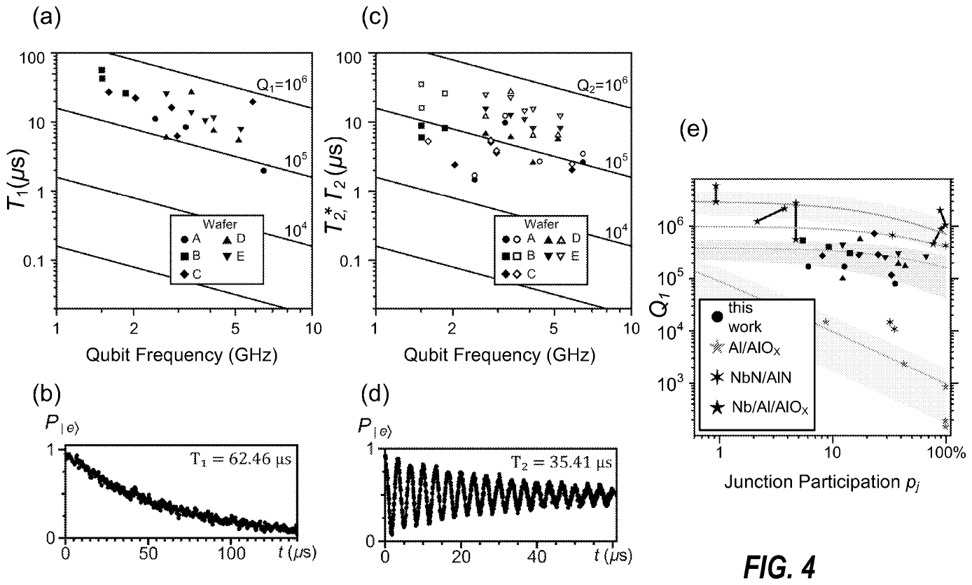

FIG. 4 shows measured properties of qubits made with the trilayer Josephson junction 100 of FIG. 1. Panel (a) is a plot of the average qubit decay time T₁, extracted by fitting the exponential decay of excited state population (see panel (b)) as a function of qubit frequency, grouped by wafer. Lines indicate qubit quality factor Q₁=ω_{q}T₁. We find an overall mean Q₁ of 2.57×10⁵ with some wafer-to-wafer variation. Panel (b) is an example plot of the exponential decay of excited state population P|e [symbol] . Panel (c) is a plot of Ramsey dephasing time

$${T}_{2}^{*}$$

(filled points) and Hahn-echo dephasing time T₂ (hollow points), extracted by fitting to the exponentially decaying and oscillating excited-state population (see panel (d)), as a function of qubit frequency. Lines indicate dephasing quality factor. We find an average

$${Q}_{2}^{*}$$

and Q₂ of 1.22×10⁵ and 2.08×10⁵, respectively. Panel (d) is an example plot of the exponentially decaying and oscillating excited-state population P|e [symbol] . Panel (e) is a plot of qubit quality factors as a function of their junction participation ratio plotted for devices in this work and in the literature. Lines and shaded confidence regions show

$${Q}_{1}^{- 1} = {p}_{j} / {Q}_{j} + {p}_{0} / {Q}_{0}$$

as a guide to the eye.

For superconducting qubits, the relaxation time and dephasing time are parameters of particular interest as they dictate qubit limitations and act as sensitive probes for loss channels. We measure relaxation time by placing each qubit in its excited state and measuring it after time t: fitting the exponential decay gives the characteristic time T₁. We perform these measurements for each qubit and show averaged results as a function of qubit frequency in panel (a) of FIG. 4, finding T₁=62.4 μs for our best device (see panel (b) in FIG. 4). To probe loss channels in detail we use the frequency-independent qubit quality factor Q₁=ω_{q}T₁, which we find for our devices is on average above 10⁵. This is within an order of magnitude of recent aluminum qubits [7, 49-52] and similar to readout resonator quality factors (see Appendix G). We also performed a Ramsey experiment to measure the dephasing time

$${T}_{2}^{*}$$

and a Hahn-echo experiment to characterize the spin-echo dephasing time T₂. We find that

$${T}_{2}^{*}$$

is within a factor of 2 of T₁, and particularly limited at lower qubit frequencies, where the environment two-level system (TLS) temperature is higher and system 1/f noise is higher (see panel (c) of FIG. 4). The T₂ values, which decouple low frequency noise, are noticeably higher, demonstrated in particular by the qubits below 2 GHz from wafer B, suggesting that more careful filtering and environment control could reduce dephasing further.

To assess loss contributions from the junction independent of other sources, in panel (e) of FIG. 4 we use the increased junction participation ratio pⱼ=cⱼ/C_{Σ} [49, 53] in our devices to examine the effects on Q₁. For our devices, we estimate an effective junction quality factor of 10⁵, approximately 100 times greater than previous Nb/Al/AlOₓ qubits [9-16], and much closer to epitaxial NbN junctions [25-27] and modern aluminum-junction qubits [49-52]. Extrapolating to lower values of pⱼ, we find our device loss is largely not limited by the junction, indicating that material refinements and device engineering could further improve qubit performance.

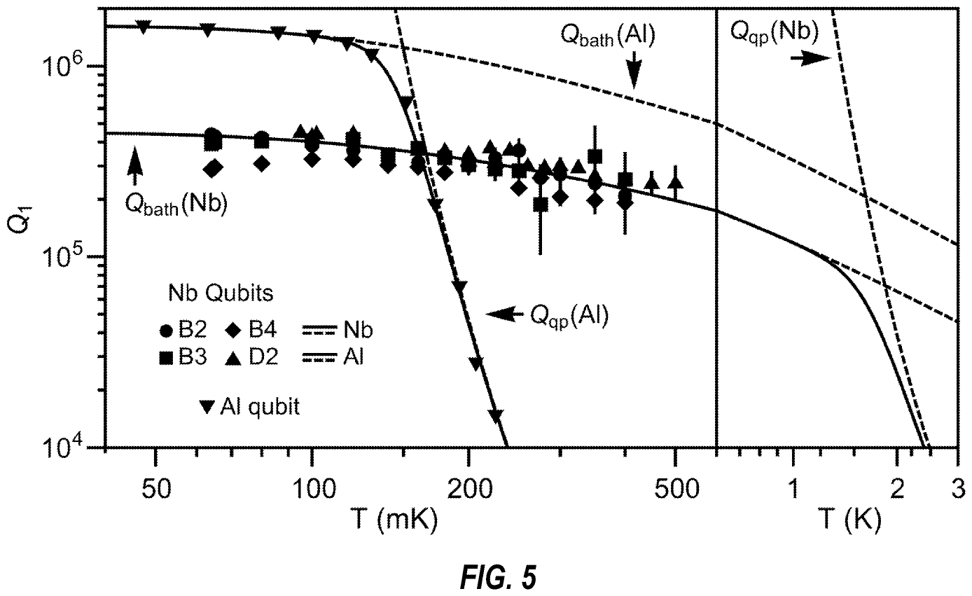

FIG. 5 is a plot of qubit quality factors from wafers B, D as a function of temperature. A mild decrease is observed at higher temperatures consistent with the system bath temperature Q_{bath}, however lifetimes are virtually unaffected by quasiparticles Q_{qp}. We also plot quality factors of an Al junction qubit, whose performance is noticeably limited by quasiparticles above 160 mK, whereas the Nb junction would not see an effect until 1.6 K.

As shown in FIG. 5, the mild decrease in T₁ with temperature above 160 mK is consistent with heating from the environment bath [14]. Importantly, we do not see the drastic temperature dependence expected for quasiparticle-induced loss [54], in line with expectations for Nb. The advantage of higher-temperature junctions is apparent when comparing our qubit performance to an Al counterpart: above 160 mK, the Al qubit is quickly overwhelmed with quasiparticle-induced decoherence, whereas our devices largely retain their properties.

We have described a Nb/Al/AlOₓ/Al/Nb trilayer fabrication method demonstrating a 100-fold improvement in junction loss at the single-photon level. By removing lossy dielectric materials wherever possible, we use our low current density junction process to fabricate microwave transmon qubits using I-line photolithography, demonstrating qubit quality factors within an order of magnitude of recent aluminum devices. Our qubits have relatively high junction participation ratios, which could either be reduced to improve coherence through material optimization [18] or exploited further to significantly reduce qubit size [24, 49]. Together with this device footprint flexibility, our all-optical qubit process opens the door to large-scale direct integration of scalable quantum processors with digital superconducting logic [21-23]. Niobium's higher energy gap significantly reduces sensitivity to quasiparticles for our junctions compared to aluminum analogues, allowing operation at much higher frequencies and resulting in far less decoherence above 160 mK where conventional qubit properties deteriorate. Combined with their low loss, these properties make the trilayer Josephson junction 100 a promising candidate for quantum architectures with lower cooling power requirements, hybrid qubit systems requiring elevated temperatures, and enable new possibilities for nonlinear elements at millimeter-wave frequencies [19, 20], paving the way for higher temperature, higher frequency quantum devices.

### Appendix A: Fabrication Methods

C-plane polished sapphire wafers are ultrasonically cleaned in toluene, acetone, methanol, isopropanol and de-ionized (DI) water, then etched in a piranha solution kept at 40° C. for 2 minutes and rinsed with de-ionized water. Immediately following, the wafers are loaded into a Plassys MEB550S electron-beam evaporation system, where they are baked at >200° C. under vacuum for an hour to help remove water and volatiles. When a sufficiently low pressure is reached (<5×10⁻⁸ mbar), titanium is electron-beam evaporated to bring the load lock pressure down even further. The trilayer is now deposited by first evaporating 80 nm of Nb at >0.5 nm/s while rotating the substrate. After cooling for a few minutes, 8 nm of aluminum is deposited while rotating the substrate at a shallow angle of 10° to improve conformality. The Al is lightly etched with a 400-V Ar⁺ beam for 10 seconds, then oxidized with a mixture of 15% O₂:Ar at a static pressure. After pumping to below 10⁻⁷ mbar, Ti is again used to bring the vacuum pressure down to the low 10⁻⁸ mbar range. We note that the pressure for the remainder of the trilayer deposition is higher than for the first Nb layer. The second 3-nm layer of Al is evaporated vertically while rotating the substrate to minimize void formation in the following layer. The counter electrode is then formed by evaporating 150 nm of Nb at >0.5 nm/s. The substrate is allowed to cool in vacuum for several minutes, and we attempt to form a thin protective coating of pure Nb₂O₅ by briefly oxidizing the top surface at 3 mbar for 30 s.

The wafers are mounted on a silicon handle wafer using AZ1518 photoresist cured at 115° C., then coated with 1 μm of AZ MiR 703 photoresist and exposed with a 375-nm laser in a Heidelberg MLA150 direct-write system. The assembly is hardened for etch resistance by a 1-minute bake at 115° C. then developed with AZ MIF 300, followed by a rinse in DI water. The entire trilayer structure is now etched in a chlorine inductively coupled plasma reactive ion etcher (see Etch 1 in Table I). The plasma conditions are optimized to be in the ballistic ion regime, which gives high etch rates with minimal re-deposition. Immediately after exposure to air, the wafer is quenched in DI water: this helps prevent excess lateral aluminum etching by quickly diluting any surface HCl (formed by adsorbed Cl reacting with water vapor in the air). The remaining photoresist is thoroughly dissolved in a mixture of 80° C. n-methyl-2-pyrrolidone with a small addition of surfactants, which also removes the substrate from the handle wafer.

The wafer is ultrasonically cleaned with acetone and isopropanol, then SiO₂ spacer is grown by either HDPCVD or PECVD. For PECVD, SiH₄ and N₂O are reacted in a 100-W plasma with the chamber at 300° C. The complete process (including chamber cleaning pumping and purging steps) takes approximately 15 minutes. For HDPCVD, the wafer is mounted on a silicon handle wafer using Crystalbond 509 adhesive softened at 135° C., then the spacer is deposited with a SiH₄, O₂, and Ar plasma, with the substrate heated to 90° C. The wafers are now etched in a fluorine reactive ion etch (see Etch 2 in Table I). This etch is optimized to be directional but in the diffusive regime to promote chemical selectivity while enabling the formation of the spacer structure. At this point, minimizing oxide formation is crucial since the top surface of the trilayer is exposed and will need to form a good contact to the wiring layer, so immediately following the completion of the etch, wafers are separated from the handle wafer by heating to 135° C., ultrasonically cleaned of remaining adhesive in 40° C. acetone and isopropanol, then immediately placed under vacuum in the deposition chamber, where they are gently heated to 50° C. for 30 minutes to remove remaining volatiles.

The contaminated and oxidized top surface of the counter electrode is etched with a 400-V Ar⁺ beam for 5 minutes, which is sufficient to remove any residual resistance from the contact. After pumping to below 10⁻⁷ mbar, titanium is used to bring the vacuum pressure down to the low 10⁻⁸ mbar range. The wiring layer is now formed by evaporating 160 nm of Nb at >0.5 nm/s. The substrate is allowed to cool in vacuum for several minutes, and the wiring layer is briefly oxidized with 15% O₂:Ar at 3 mbar for 30 seconds to promote a thin protective coating of pure Nb₂O₅. The wafers are again mounted on a handle wafer, coated with AZ MIR 703 photoresist and exposed with a 375-nm laser. The assembly is hardened for etch resistance by a 1 min bake at 115° C. before development. The final structure is now defined with a fluorine reactive ion etch (Etch 3 in Table I). This step proves to be highly problematic as it easily forms inert residues, and needs to be highly chemically selective in order to avoid etching through the aluminum, so the plasma is operated in a low-density ballistic regime with the addition of O₂ which helps passivate exposed aluminum and increase selectivity. The etch time is calculated for each wafer based on visual confirmation when the bare wiring layer is etched through. We remove crosslinked polymers from the photoresist surface with a mild 180-W room-temperature oxygen plasma that minimally oxidizes the exposed Nb. The remaining resist is now fully dissolved in 80° C. n-methyl-2-pyrrolidone with surfactants.

TABLE 1
Parameters used in the ICP-RIE etches. Etches were performed in an Apex
SLR ICP etcher. The top half of the table lists gas flows (by species) in sccm.

| Etch | Cl₂ | BCl₃ | Ar | CF₄ | CHF₃ | SF₆ | O₂ |
|---|---|---|---|---|---|---|---|
| 1: FIG. 2A, (b) | 30 | 30 | 10 | — | — | — | — |
| 2: FIG. 2A, (d) | — | | 10 | 30 | 20 | — | — |
| 3: FIG. 2A, (f) | — | | 7 | — | 20 | 40 | 4 |

| | | Pressure | ICP Power | Bias Power | Etch Time | Etch Rate |
|---|---|---|---|---|---|---|
| Etch | T (° C.) | (mT) | (W) | (W) | (s) | (nm/s) |
| 1: FIG. 2A, (b) | 20 ± 0.1 | 5 | 400 | 50 | 50-60 | ~4.5 |
| 2: FIG. 2A, (d) | 20 ± 0.1 | 30 | 500 | 60 | 120-140 | ~2 |
| 3: FIG. 2A, (f) | 20 ± 0.1 | 5 | 400 | 60 | 65-90 | ~4.5 |

With the junctions now formed, the wafer is ultrasonically cleaned with acetone and isopropanol, coated with a thick protective covering of photoresist (MiR 703) cured at 115° C., and diced into 7-mm chips. The protective covering is dissolved in 80° C. n-methyl-2-pyrrolidone with surfactants (we find this can also help remove stubborn organic residues from previous steps), and the chips are given a final ultrasonic clean with acetone and isopropanol. The remaining silicon spacer is now dissolved by a short 10-15 second etch in a mixture of ammonium fluoride and acetic acid (AIPAD Etch 639), quenched in de-ionized water, then carefully dried from isopropanol to preserve the now partially suspended wiring layer. The finished chips are packaged and cooled down within a couple of hours from this final etch to minimize any NbOₓ regrowth from air exposure.

### Appendix B: Junction Superconductor Properties

Josephson junction properties are largely determined by the characteristics of the two superconductors and the insulating oxide barrier that separates them, so the initial formation of the trilayer materials is crucial for the device quality. As Nb sets the limit of superconducting properties and losses in our junctions and qubits, it is crucial to begin with a high-quality and thus high-purity material. Maintaining material purity presents a challenge for any thin film deposition technique, made difficult in particular by the incorporation of contaminants into the film during growth. This contamination can be addressed with two main approaches: first by reducing the flux of contaminants (achieved by reducing the vacuum pressure during the deposition process), but also by reducing the duration of exposure, which can be controlled by the deposition rate.

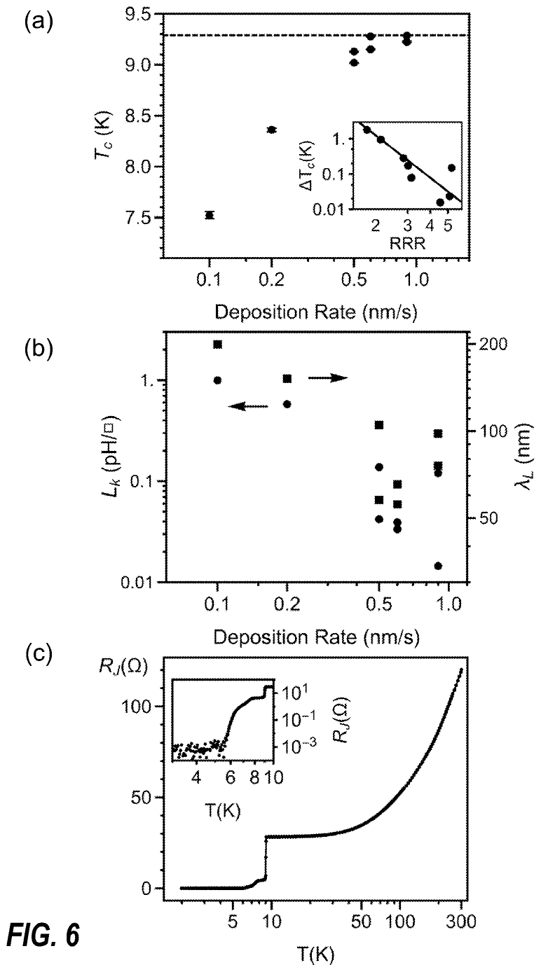

For electron beam evaporation (i.e., the deposition technique used here), vacuum pressures are reduced as low as possible during deposition. However, the pressures are limited to the 10⁻⁸ mbar range by the hardware. With the contaminant flux fixed by the deposition system vacuum pressure, we explore the effect of deposition rate on Nb purity. By measuring the resistivity of a film with a known geometry at varying temperatures, we obtain a wealth of information about the film properties. In panel (a) of FIG. 6, we plot the superconducting transition temperature T_{c}=Δ₀/(1.76 k_{B}) (proportional to the superconducting gap Δ₀) as a function of metal deposition rate. We observe that higher rates yield increased transition temperatures, which approach those found in bulk high-purity Nb [55], indicating that the films are increasingly pure. Indeed, we can also correlate the residual resistivity ratio RRR=ρ(300 K)/ρ(T_{C}), an indicator of superconductor quality, with deviations of measured critical temperature the bulk value T_{C}^{bulk}, supporting the notion that higher deposition rates yield higher-quality films. Due to the extreme local temperatures required, practical considerations and stability concerns put a limit on feasible deposition rates. Nonetheless, despite variations induced by vacuum conditions, we find that rates above 0.6 nm/s are required to deposit a film with high purity.

We can go further to examine the degree of disorder in the superconductor by probing the kinetic sheet inductance L_{K}=ℏR_{□}/(πΔ₀), where R_{□}=ρ₀/t is extracted from the film thickness t, and the resistivity just above the superconducting transition. The sheet inductance also yields the London magnetic penetration depth

$${λ}_{L}^{2} = {tL}_{K} / {μ}_{0} .$$

In panel (b) of FIG. 6, we find that both L_{K} and λ_{L} are also reduced with films deposited at higher rates. Lower kinetic inductance and shorter London lengths indicate a lower degree of disorder in the superconductor, suggesting that increased deposition rates bring the material further away from the disordered dirty superconductor limit (λ_{L}>>ξ) [56].

We verify the superconducting contact quality between the wiring layer and the counter electrode, as well as the junction tunnel barrier transparency by measuring the voltage across a chain of 12 junctions in series, through which we send a fixed excitation current of 10 μA. In panel (c) of FIG. 6, we plot the per-junction specific resistance R_{J} as a function of temperature, showing the immediately apparent superconducting transition above 9 K. Immediately below the transition, the superconducting gap is still relatively low, and the junction critical currents fall below the excitation current, so a small resistance is observed. However as we decrease the temperature, we find that the resistance shrinks by several orders of magnitude (below the noise floor of the instrument). This indicates that the sum of any remaining resistance channels in a single junction is likely well below the mΩ range, suggesting a superconducting contact between the Nb wiring layer and the Nb counter electrode.

FIG. 6 illustrates superconductor material quality. Panel (a) is a plot of niobium superconducting critical temperature T_{C} extracted from resistivity measurements as a function of metal deposition rate. At deposition rates above 0.6 nm/s, T_{C} approaches bulk value (dashed line). The inset shows how deviations from bulk

$$Δ {T}_{C} = {T}_{C}^{b u l k} - {T}_{C}$$

are correlated with the residual resistivity ratio, implying high deposition rates result in high-quality films. Panel (b) is a plot of sheet kinetic inductance L_{K} and observed London penetration depth λ_{L} as a function of deposition rate. This plot suggests that films deposited at higher rates are closer to the clean superconductor limit. Panel (c) is a plot of specific junction resistance R_{J}=R/N obtained by measuring the resistance R of a chain of N=12 junctions as a function of temperature T. A sharp drop in resistance is observed above 9 K as the niobium electrodes begin to superconduct. As the temperature decreases, the junction critical currents increase above the excitation current (10 μA), and below 5 K the measured resistance drops to zero as the excitation is confined to the superconducting branch, indicating proximity of the aluminum and superconducting contact between the counter electrode and wiring layers.

### Appendix C: Lossy Plasma Etch Residues

By virtue of size, the electric field concentration in a junction is orders of magnitude higher than in the qubit capacitor (or any planar structure such as the resonator capacitor), meaning the participation ratio [53] of the junction side surfaces will also be much higher. As such, our junction loss is likely still limited by the presence of lossy dielectrics formed on the sides of the junction, which for our design are primarily either spacer material, metal oxides, or residues left by the reactive ion etching process. As we cannot use more aggressive spacer [36] or oxide removal methods [18] without further risking the integrity of the Al junction barrier, we instead study the etch residues and discuss mitigation strategies.

Alongside the desired chemical and mechanical processes that remove Nb, reactive ion etching hosts a variety of simultaneous mechanisms that can grow material: etched material can either be re-deposited by sputtering, low-energy reaction products can re-adsorb onto exposed surfaces, and components in the plasma can react with exposed material [34]. The products of all of these mechanisms tend to be much more difficult to remove, so end up staying behind after the photoresist is dissolved, particularly on vertical walls not directly exposed to plasma bombardment during the etch. While the deposited material passivates the walls of the etched region during the etch and can produce high-aspect ratio features, for our junctions its critical to reduce any excess dielectrics, so we explore ways to understand and mitigate these residues in order to reduce loss.

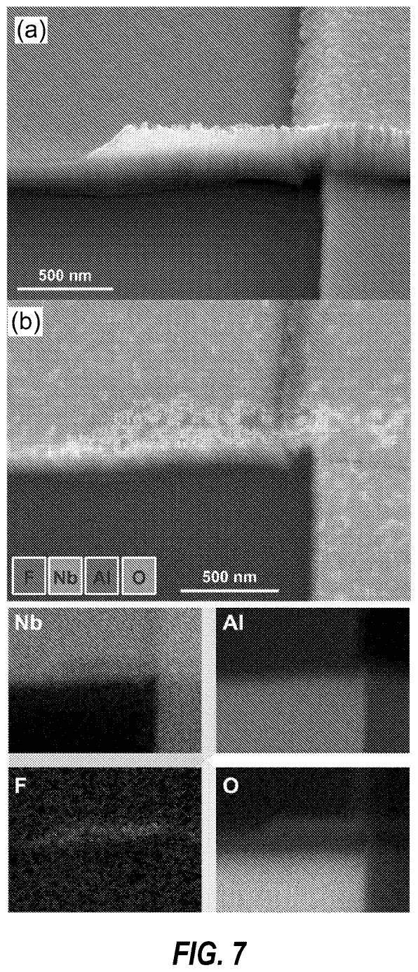

In FIG. 7, we show an example of a dielectric residue located on the side of a junction which has not been entirely removed throughout the entire fabrication process. This material must be formed during the third dry etch (see FIG. 2A, panel (f)) since it covers and extends off the sides of the Nb wiring and counter-electrode layers. The residues appear to be present on all vertical surfaces exposed by the etch, visible as striations on the junction sides. To determine the deposition mechanism for this residue, we probe the chemical composition of the residue using energy dispersive spectroscopy (EDS). A composite map of normalized element composition is overlaid on the same image of the residue in panel (b) of FIG. 7, with individual normalized element concentration maps shown to the right. As expected, we observe high Nb concentrations in the metal regions, and high Al and oxygen concentrations in the sapphire region, but more importantly we observe a significant concentration of fluorine in the residue (carbon is also observed in this region as well, but cannot be quantified due to high background carbon levels). This suggests the residue is some kind of fluorocarbon polymer.

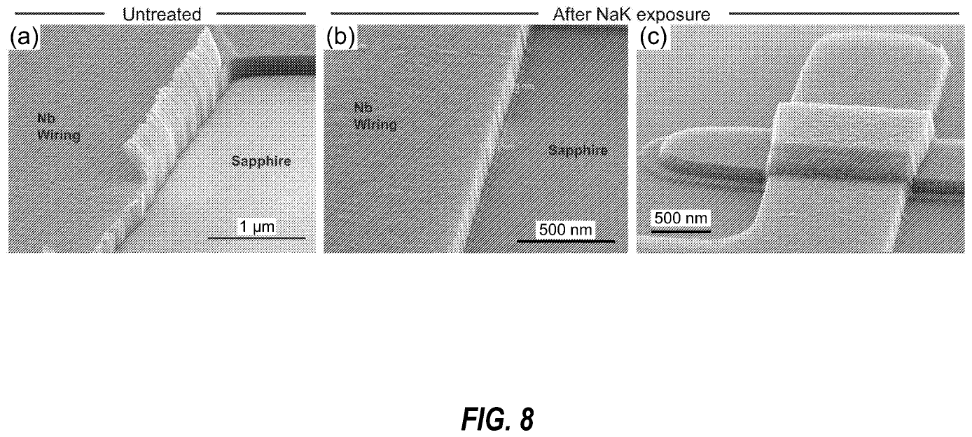

Fluorocarbons are chemically inert and robust against most standard solvents, acids, or oxygen plasma, and the residues remain largely unaffected by these conditions. However, fluorocarbon polymers are susceptible to defluorination by strong alkali reductants such as sodium-potassium amalgam (NaK) [57, 58]. In panel (a) of FIG. 8, we show a device with particularly extensive residues covering and extending off the sides of the wiring layer. In an oxygen-free dry nitrogen glovebox, we immerse the sample surface in a sodium-potassium amalgam (NaK) for 15 minutes, rinse with tetrahydrofuran, move the sample into air, finish rinsing with acetone and isopropanol, then image the residues. In panels (b) and (c) of FIG. 8, we observe that the residue material is largely removed. The overhanging features are gone, as well as the material on the metal sides, with the original extent of the residue (about 30 nm) apparent by the indentation left on the sapphire by the residue during the etch. This corroborates the hypothesis that these residues are composed of fluorocarbons, since the material could be removed upon treatment with Nak, wherein the amalgam cleaves the problematic C—F bonds and allows the remaining residues to become soluble in organic solvents.

While this NaK treatment appears promising on the microscopic scale, in practice the amalgam is difficult to keep clean, and leaves behind significant quantities of dust and salt deposits on the chip surface. A more practical method to post-clean any residues left behind by the etch might be to instead use a solution with a high reducing potential such as sodium napthalenide [57], commonly used as a surface treatment for polytetrafluoroethylene (PTFE). Regardless, the best way to remove the residues is to not form them in the first place, which is achieved by optimizing the etch plasma conditions. First, we remove obvious residue sources by ensuring the plasma chamber is thoroughly cleaned with oxygen, and no fluorinated vacuum oils are present in the system. We find that using gas constituents with low hydrogen and carbon content (e.g., SF₆ or CF₄) significantly reduces the residue growth: in particular, we find CHF₃ and C₄F₈ readily polymerize. However, we note that using too much SF₆ can lead to the incorporation of sulfur [59] into any exposed SiO₂, which forms an even more inert residue and should be avoided. The addition of O₂ in the plasma can also help increase the carbon-fluorine ratio of the plasma [60], but also increases resist etch rate and passivates exposed metal. Using a low density plasma with a long mean free path for the radicals is key to increasing the etch rate and reducing re-deposition, as it increases the effective reactant and product temperature. Residue formation is also particularly sensitive to substrate temperature. With the substrate too cold, the reaction product temperature becomes low enough to allow recondensing, leading to increased fluorocarbon deposition. If the substrate is too hot, reactivity of the photoresist polymers is increased, promoting crosslinking, polymerization, and fluorination: thus good thermal contact between the substrate and the carrier wafer is essential, as the high temperature plasma can otherwise significantly heat the substrate. Finally, we observe the residue formation accelerates when the insulating substrate is exposed (likely a result of screening charges focusing the plasma towards remaining metal), so we ensure the etch is stopped within 15 seconds of completion.

FIG. 7 illustrates etch residue chemical analysis. Panel (a) is a scanning electron micrograph of plasma etch residue located on the wiring layer near a junction. Panel (b) is a composite EDS image overlaid on the image of panel (a) showing normalized element density regions for F, Nb, Al, and O, with individual element density maps shown in their respective color on the right. Along with clear Nb and sapphire (Al₂O₃) regions, a high concentration of fluorine relative to the background is found in the residue region, suggesting the residue is composed of fluorinated polymers.

FIG. 8 illustrates etch residue Nak reactivity. Panel (a) is a scanning electron micrograph of plasma-etch residue on the edges of the wiring layer. A closer inspection of the bottom left reveals that the residue extends to cover the sides of the metal, even where the top crust has been mechanically removed. In panels (b) and (c), the wiring layer and a junction from the same wafer imaged after a 15-min exposure to NaK amalgam showing nearly complete removal of the etch residue.

### Appendix D: Junction Area Dependence

Having verified the relationship between the normal state resistance Rₙ, the critical current and the gap energy (see FIG. 3), we can use room temperature resistance measurements to efficiently predict cryogenic junction properties. In panel (a) of FIG. 8, we show room-temperature junction resistance and junction inductance (calculated from resistance using the I_{c}R_{N} product), plotted as a function of junction area (corrected for lithographic reduction). The original untreated (see FIG. 2A, panel (f)) junction resistances are in good agreement with the expected inverse dependence on junction area, enabling us to fit the original critical current density. After etching the spacer (see FIG. 2A, panel (g)) some of the aluminum is removed as well, and the resistance increases since the effective junction dimensions have shrunk. By fitting the etched junctions, we extract a dimension reduction of approximately 160 nm, which corresponds to about 80 nm of aluminum that gets removed by the etch. We note that this sets a practical limit on how small the junction can be before etching effects become more significant than lithographic definition of junction area.

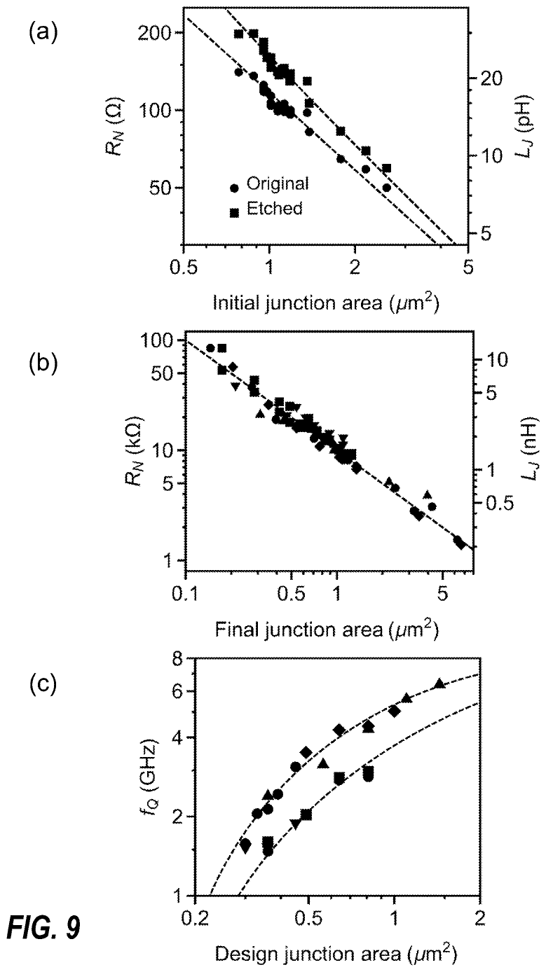

Fitting junction resistances as a function of the final junction area (accounting for the dimension reductions) yields the true critical current density for the final junctions (see panel (b) in FIG. 9). We repeat these measurements for wafers with different processing conditions to populate the plot in panel (b) in FIG. 3. A spread (typically between 5-10%) is noticeable in our junction resistance for a given junction area. While higher than typical Nb trilayer junction non-uniformity [29, 30], our junction variance can primarily be attributed to relatively large geometric deviations due to the limits of our lithographic resolution, which is compounded by fluctuations in the etch dynamics that determine the final junction area. Because of this, we cannot probe the uniformity of the trilayer barrier itself, however we estimate that it behaves similarly to other trilayer junctions investigated, implying that our junction parameter spread could likely be reduced with higher resolution lithography methods and a more selective spacer removal technique. We test the functional limits of our junction reproducibility by measuring deviations of qubit frequencies across different chips from different wafers. In panel (c) of FIG. 9, we show qubit frequencies (determined by junction inductance) as a function of design qubit junction area for devices with two different qubit capacitor designs. After determining the qubit capacitance and applying the estimated junction area reductions, we find the measured frequencies are self-consistent within 10% or so, even across separate wafers.

FIG. 9 illustrates how properties of the trilayer Josephson junction 100 of FIG. 1 depend on junction area. Panel (a) is a plot of room-temperature junction resistance and junction inductance as a function of junction area (corrected for lithographic reduction). Original untreated junction resistances are shown as circles and etched junctions as squares, with fits to an inverse relationship to area (dashed lines) yielding the original critical current density J_{c} and an etch dimension reduction of approximately 160 nm. Panel (b) is a plot of junction resistances as a function of the final junction area with a inverse fit (dashed line) which gives the critical current density. For illustrative purposes, we have shown PECVD junctions in panel (a) and HDPCVD junctions in panel (b). Panel (c) is a plot of qubit frequencies as a function of design junction area for devices with two different qubit capacitor designs, with qubits from the same wafers grouped by data-point shape.

### Appendix E: Junction Annealing Mechanism

The effect of process temperature is readily apparent when comparing the resulting critical current densities of junctions with PECVD spacers (deposited at 300° C.) and those with HDPCVD-grown spacers (90° C.). In panel (b) of FIG. 3, for the high-temperature PECVD junctions, we observed an approximately 2.3% reduction in J_{c}. We investigate this effect in more detail by annealing finished low-temperature (HDPCVD) junctions with initial J_{c0}~3 kA cm⁻² in a dry Ar atmosphere, then re-measuring their critical current density.

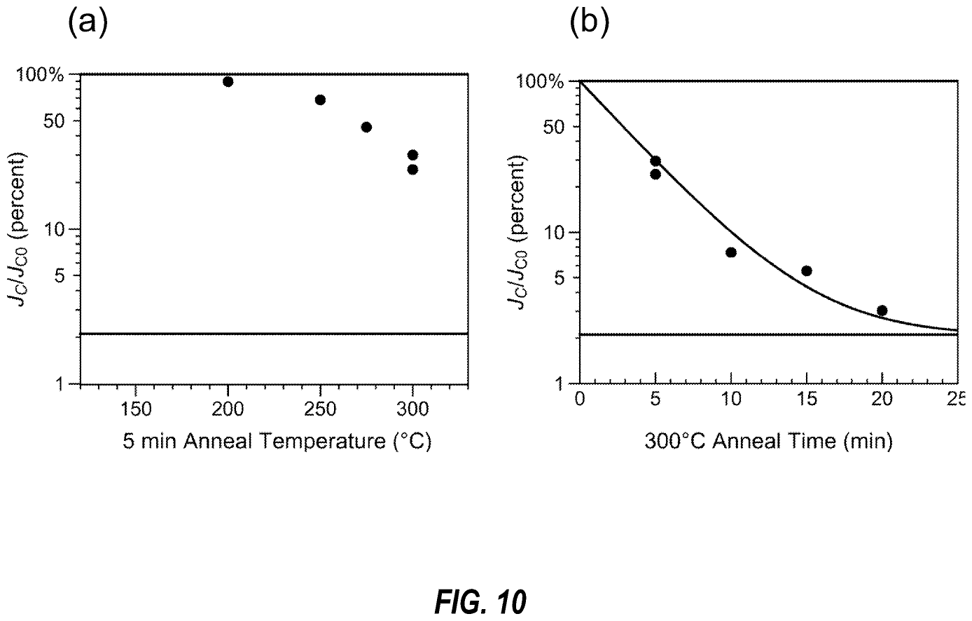

In panel (a) of FIG. 10, we plot the annealed J_{c} as a percentage of the untreated J_{c0} and confirm that the annealing effect activates above 200° C., in agreement with [38]. In panel (b) of FIG. 10, we show the critical current density of junctions annealed at 300° C. for various lengths of time. After about 20 min (the approximate time wafers spend at 300° C. during PECVD), we find that the current density reduction approaches the measured ratio between the PECVD and HDPCVD junctions. This suggests the high-temperature process dynamically anneals the junction barrier, likely increasing mobility and in the oxide barrier which enables diffusion and reduces pinhole density [46]. Qualitatively, this process appears to be exponential in time, so we overlay a saturating exponential fit of the form

$${J}_{c} / {J}_{c}^{0} = ( 1 - α ) {e}^{- t / τ} + α ,$$

where α is the observed reduction factor, and obtain a critical time τ≈4 min. The observed annealing effect is consistent with the critical current densities measured in Ref. [28], which do not exceed 190° C. during the fabrication process. With this in mind, our PECVD process could be modified to produce high critical current density junctions by either reducing the deposition temperature below 200° C. or to a lesser extent by limiting the time spent at elevated temperatures.

FIG. 10 illustrates the effects of annealing on the performance of the Josephson junction 100 of FIG. 1. Panel (a) is a plot of HDPCVD junction critical current density reduction after annealing for 5 minutes as a function of annealing temperature. The plot shows activation at 250° C. Panel (b) is a plot of critical current density reduction as a function of annealing time at 300° C., which approaches the factor-of-50 reduction observed in the main text (horizontal lines). The curved solid line in panel (b) is an exponential fit that saturates at the observed reduction factor.

### Appendix F: Qubit Geometry and Experimental Setup

The qubit, readout resonator, and other structures are formed in the same steps as the junction. We base our design on a qubit geometry [48] popular for its reduced radiation profile, a result of the cross-shaped coplanar qubit capacitor whose local electric dipole moments act to cancel each other out far away. In our case, the cross shape (typically used to implement qubit-qubit coupling or additional charge drives) is not strictly necessary and a coplanar capacitor composed of any two-dimensional shape would work as well. We also try to minimize coupling to lossy two-level systems in surface dielectrics by rounding sharp corners where possible in the geometry. This reduces electric field concentration at specific points in the capacitor, leaving a weaker and more homogenous electric field which should couple less strongly to individual two-level systems.

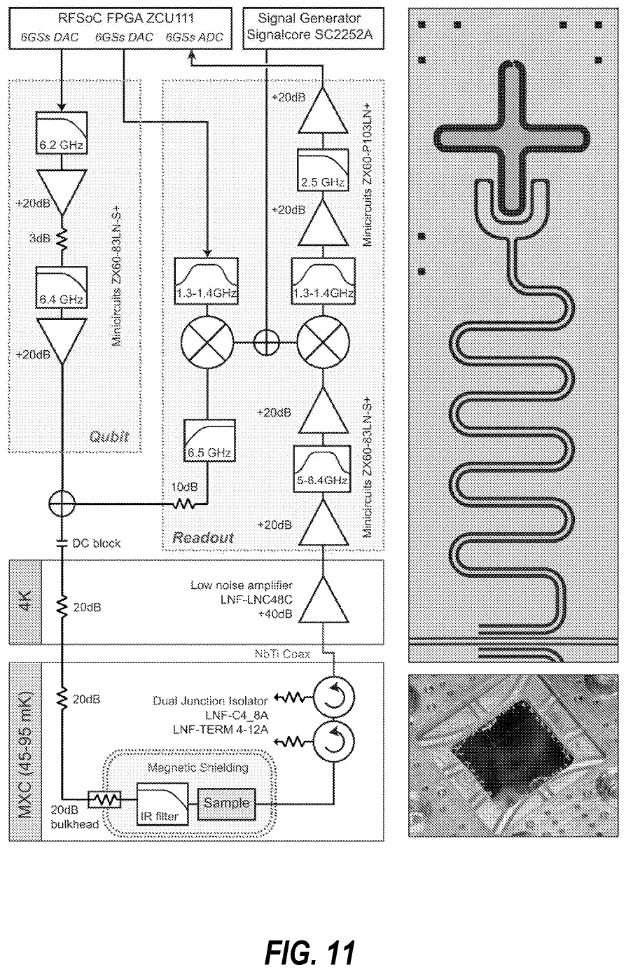

An example of our qubit geometry is shown in a composite microscope image on the top right of FIG. 11, which was taken after Etch 3 (see FIG. 2A, step (f)). The Nb and unetched Al appear differently, allowing us to distinguish between the wiring layer and the base electrode. In our geometry, the qubit capacitor is formed with both layers while the rest of the circuit and the majority of the chip (e.g., ground plane, readout resonator, coupling waveguides, etc.) is formed with just one layer. We find that the wiring layer readout resonators exhibit lower loss (see Appendix G), so we typically pick the wiring layer for the ground plane. However having measured devices with both configurations (majority wiring layer and majority base electrode), we do not find significant differences in qubit properties, where the fields participate in both layers regardless of orientation. As an example, compare base-electrode ground plane wafer D with wiring ground plane wafer A in panel (a) of FIG. 4, whose qubit quality factors are similar.

The qubits are capacitively coupled to a meandered quarter-wave coplanar waveguide resonator, which is in turn inductively coupled to a transmission line for readout. For simplicity, we couple directly to the readout resonator without additional Purcell filtering. Chips containing up to six qubits and resonators are mounted in a copper circuit board shown in the bottom right of FIG. 11, which is in turn bolted to a copper post that thermalizes the assembly to the base temperature of an Oxford Triton 200 dilution refrigerator with minimum mixing chamber temperatures between 45-95 mK. The mounted assembly is encased in two layers of mu-metal magnetic shielding to reduce decoherence from stray magnetic fields, the qubits are isolated from microwave noise through an Eccosorb CR-110 high-frequency absorbing filter as 60 dB of cryogenic attenuation which keep the input noise close to the mixing chamber temperature. Transmitted microwave signals pass through two wideband circulators (isolating the qubits from microwave noise from the output side) into a low-loss superconducting NbTi coaxial cable, then are amplified by a low-noise cryogenic amplifier followed by additional room temperature amplification.

Resonators and qubit transitions are characterized with single and two-tone spectroscopy using an Agilent E5071C network analyzer. For pulsed qubit measurements, we use a Quantum Instrument Control Kit [61] based on the Xilinx RFSoC ZCU111 FPGA. Qubit pulses are directly synthesized by the FPGA, while measurement pulses are generated with a heterodyne conversion setup, as shown in the schematic of FIG. 11. With the spectral layout of each device determined, we select filter networks to minimize unwanted images and harmonics from the FPGA for both the qubit and readout pulses, with a broadband example configuration shown in FIG. 11. The FPGA and carrier signal generator are clocked to a 10-MHz rubidium source for frequency stability.

### Appendix G: Material Loss Probed by Resonator Quality Factor

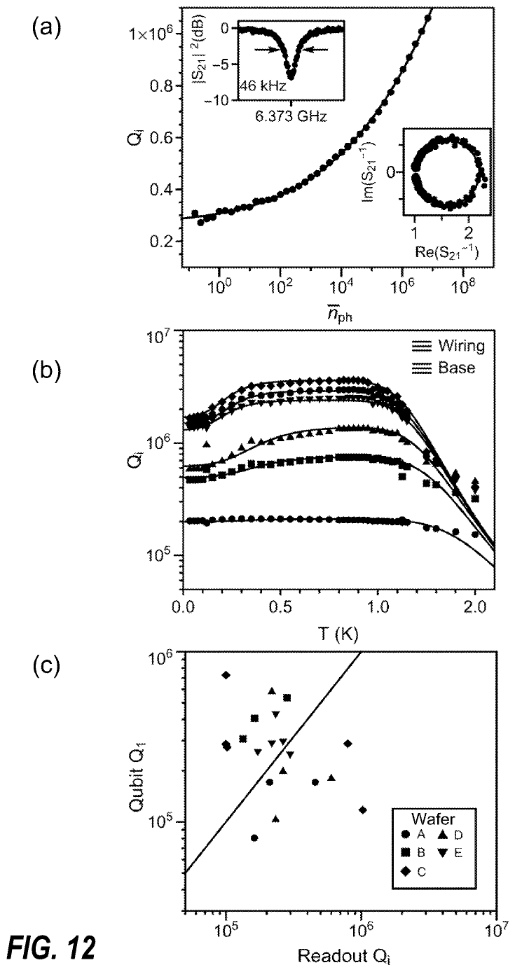

To compare qubit loss contributions from material sources with contributions from the junction itself, we measure quality factors for readout resonators subject to the same fabrication conditions, but with no qubits attached. A typical normalized transmission spectrum of a resonator taken at a low average photon number n̅ₚₕ≈0.96 is shown in the inset of FIG. 12, panel (a). On resonance, we observe a dip in magnitude, which at low powers is described well by [62]:

$${S}_{21} = 1 - \frac{Q}{{Q}_{e}^{*}} \frac{{e}^{i ϕ}}{1 + 2 i Q ( ω - {ω}_{0} ) / {ω}_{0}} \qquad ( 1 )$$

where

$${Q}^{- 1} = {Q}_{i}^{- 1} + Re [ {Q}_{e}^{- 1} ]$$

and the coupling quality factor

$${Q}_{e} = {Q}_{e}^{*} {e}^{- i ϕ}$$

had undergone a complex rotation φ due to minor impedance mismatches. We plot fitted internal quality factors in panel (a) of FIG. 12, finding that Qᵢ increases with power. This behavior is entirely captured by a power dependent saturation mechanism [63], suggesting the dominant loss mechanism in the resonators arises from coupling to two-level systems.

We further investigate limits on the resonator loss by using increased temperatures to further saturate the two-level systems. In panel (b) of FIG. 12, we plot Qᵢ measured at n̅ₚₕ∓10⁴ as a function of temperature (grouped by fabrication layer), with solid lines corresponding to a model of the form

$${{Q}_{i} ( T )}^{- 1} = {Q}_{other}^{- 1} + {{Q}_{T L S} ( T )}^{- 1} + {{Q}_{σ} ( T )}^{- 1} \qquad ( 2 )$$

where Q_{TLS} is the saturating loss mechanism from two-level systems [63], Qₒₜₕₑᵣ is a temperature-independent upper bound arising from other sources of loss, and the conduction loss Q_{σ} is given by [54]:

$${Q}_{σ} ( T ) = \frac{1}{α} \frac{{σ}_{2} ( T , {T}_{c} )}{{σ}_{1} ( T , {T}_{c} )} \qquad ( 3 )$$

where σ₁ and σ₂ are the real and imaginary parts, respectively, of the complex surface impedance, calculated by numerically integrating the Mattis-Bardeen equations for σ₁/σₙ and σ₂/σₙ [54]. The critical temperature T_{c} is constrained to the values measured in Appendix B, and a is used as a fit parameter.

Comparing resonators formed during different steps in the fabrication process, we observe that resonators made from the wiring layer exhibit consistently higher quality factors, while resonators from the base layer are lossier and much more variable. Since the sides of the base layer have been exposed to more fabrication steps than the wiring layer, the surface niobium of this layer has a much longer chance to oxidize, and has the additional potential to host lossy dielectrics from un-removed spacer material. Thus, while we have improved losses in the wiring layer to about Q_{TLS}~0.9×10⁶ by reducing fluorocarbon formation, our devices are still loss-limited to approximately 2×10⁵ by two-level systems in the surfaces of the base electrode.

To investigate the relationship between qubit and readout resonator decoherence, we also measure quality factors of the readout resonator for each qubit. At single-photon powers, the readout resonator is maximally susceptible to material-based loss from two-level systems in its surface, but due to the hybridization of its electric field with the qubit mode will also interact with the materials in the qubit. In panel (c) of FIG. 12, we compare qubit quality factors Q₁ with the single-photon readout quality factor Qᵢ for each of the devices from FIG. 4. On average, we observe that the two quality factors are close to a one-to-one relationship (as indicated by the solid line), with device variations within a factor of three or so. While a direct correlation between the two cannot be extracted from this data, this is to be expected for loss dominated by inhomogeneous material defect distributions between the resonator and qubit. Nevertheless, the similarity of the two quality factors leads us to conclude the qubit and resonator are likely limited by similar decoherence mechanisms.

FIG. 12 illustrates material loss, as probed by resonator quality factor. Panel (a) is a plot showing the power dependence of the internal quality factor for a readout resonator (Qₑ=2.6×10⁵) with no qubit present. The solid line is a fit to a model that includes loss from two-level systems (TLS). The insets show the lineshape and fits at an average photon occupation n̅ₚₕ≈0.96. Panel (b) is a plot of the internal quality factor of resonators without qubits measured as a function of temperature. Solid lines are fits to a model including TLS loss and quasiparticle loss. The three data sets at the top of the plot are for resonators formed from the wiring layer, and the three data sets at the middle and bottom of the plot are for resonators from the base electrode. Measurements are taken n̅ₚₕ≈10⁴ so some TLS loss is saturated. Panel (c) is a plot of qubit quality factors Q₁ as a function of their readout resonator quality factors Qᵢ (measured at nₚₕ<1). The solid line indicates a 1:1 relationship.

### Combinations of Features

Features described above as well as those claimed below may be combined in various ways without departing from the scope hereof. The following examples illustrate possible, non-limiting combinations of features and embodiments described above. It should be clear that other changes and modifications may be made to the present embodiments without departing from the spirit and scope of this invention:

(A1) A Josephson junction includes a substrate, a trilayer stack, and a wiring layer. The trilayer stack includes a base electrode located directly on a top face of the substrate, an internal layer located on top of the base electrode, a barrier layer located on top of the internal layer, and a counter electrode located on top of the barrier layer and fully covering the barrier layer. The wiring layer is electrically connected to the counter electrode and includes a top section located directly on top of the counter electrode, a bottom section located directly on the top face of the substrate and adjacent to the base electrode, and a middle section directly connecting between the top section and the bottom section such that the middle section forms a gap with the trilayer stack. No spacer material directly contacts the trilayer stack.

(A2) In the Josephson junction denoted (A1), the gap is devoid of solid-state material.

(A3) In either of the Josephson junctions denoted (A1) and (A2), the spacer material includes silicon oxide.

(A4) In any of the Josephson junctions denoted (A1) to (A3), the base electrode is made from a first type of superconducting material, the internal layer is made from a second type of superconducting material different from the first type of superconducting material, and the counter electrode is made from the first type of superconducting material.

(A5) In the Josephson junction denoted (A4), the first type of superconducting material includes at least one of the materials in the group consisting of: niobium, niobium nitride, titanium nitride, aluminum, and aluminum nitride.

(A6) In either of the Josephson junctions denoted (A3) and (A4), the second type of superconducting material includes at least one of the materials in the group consisting of: aluminum and niobium nitride.

(A7) In any of the Josephson junctions denoted (A1) to (A6), the barrier layer includes at least one material in the group consisting of: aluminum, aluminum oxide, aluminum nitride, titanium, and niobium oxide.

(A8) In any of the Josephson junctions denoted (A1) to (A7), the barrier layer fully covers the internal layer.

(A9) In any of the Josephson junctions denoted (A1) to (A8), the top section of the wiring layer fully covering a top face of the counter electrode.

(A10) In any of the Josephson junctions denoted (A1) to (A9), the base electrode is shaped as a rectangular prism having (i) a prism width along a first direction parallel to the top face of the substrate and (ii) a prism length greater than the prism width along a second direction that is parallel to the top face and perpendicular to the first direction. The counter electrode has a counter-electrode length, along the second direction, that is less than the prism length. The wiring layer has a wiring-layer length along the first direction that is greater than the prism width.

(A11) In any of the Josephson junctions denoted (A1) to (A10), the wiring layer includes a first bottom section located directly on the top face of the substrate and adjacent to a first side of the base electrode. The wiring layer also includes a second bottom section located directly on the top face of the substrate and adjacent to a second side of the base electrode that is opposite to the first side. The wiring layer also includes a first middle section directly connecting between a first edge of the top section and the first bottom section such that the first middle section forms a first gap with the trilayer stack. The wiring layer also includes a second middle section directly connecting between a second edge of the top section, opposite to the first edge, and the second bottom section such that the second middle section forms a second gap with the trilayer stack.

(A12) In the Josephson junction denoted (A11), each of the first gap and the second gap is completely devoid of solid-state material.

(A13) In any of the Josephson junctions denoted (A1) to (A12), the Josephson junction further includes a capping layer located between the barrier layer and the counter electrode.

(A14) In the Josephson junction denoted (A13), the capping layer has a thickness of 10 nm or less.

(A15) In either of the Josephson junctions denoted (A13) and (A14), the capping layer fully covers the barrier layer and the counter electrode fully covers the capping layer.

(A16) In any of the Josephson junctions denoted (A13) to (A15), the base electrode and the counter electrode are made from niobium, the internal layer and the capping layer are made from aluminum, and the barrier layer is made from aluminum oxide.

(A17) In any of the Josephson junctions denoted (A1) to (A16), the substrate is made from sapphire.

(A18) In any of the Josephson junctions denoted (A1) to (A17), the Josephson junction has a critical current density less than or equal to 10 kA/cm².

(A19) In any of the Josephson junctions denoted (A1) to (A18), the Josephson junction has a junction area less than or equal to 1 μm².

(A20) In any of the Josephson junctions denoted (A1) to (A19), the Josephson junction has a coherence time exceeding 16 μs.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

### REFERENCES

[1] B. Jeanneret and S. P. Benz, Eur. Phys. J.: Spec. Top. 172, 181 (2009).
[2] R. Vijay, M. H. Devoret, and I. Siddiqi, Rev. Sci. Instrum. 80, 111101 (2009).
[3] A. I. Braginski, J. Supercond. November Magn. 32, 23 (2019).
[4] I. V. Vernik, A. F. Kirichenko, O. A. Mukhanov, and T. A. Ohki, IEEE Trans. Appl. Supercond. 27, 1 (2017).
[5] K. K. LOikharev and V. K. Semenov, IEEE Trans. Appl. Supercond. 1, 3 (1991).
[6] S. K. Tolpygo and V. K. Semenov, J Phys. Conf. Ser. 1559, 012002 (2020).
[7] M. Kjaergaard, M. E. Schwartz, J. Braumüller, P. Krantz, J. I.-J. Wang, S. Gustavsson, and W. D. Oliver, Annu. Rev. Condens. Matter Phys. 11, 369 (2020).
[8] D. K. Finnemore, T. F. Stromberg, and C. A. Swenson, Phys. Rev. 149, 231 (1966).
[9] S. K. Dutta, H. Xu, A. J. Berkley, R. C. Ramos, M. A. Gubrud, J. R. Anderson, C. J. Lobb, and F. C. Wellstood, Phys. Rev. B 70, 140502 (2004).
[10] J. M. Martinis, S. Nam, J. Aumentado, and C. Urbina, Phys. Rev. Lett. 89, 117901 (2002).
[11] H. Paik et al., Phys. Rev. B 77, 214510 (2008).
[12] M. Weides et al., Supercond. Sci. Technol. 24, 055005 (2011).
[13] Ch. Kaiser et al., Supercond. Sci. Technol. 24, 035005 (2010).
[14] J. Lisenfeld, A. Lukashenko, M. Ansmann, J. M. Martinis, and A. V. Ustinov, Phys. Rev. Lett. 99, 170504 (2007).
[15] Y. Yu, D. Nakada, J. C. Lee, B. Singh, D. S. Crankshaw, T. P. Orlando, K. K. Berggren, and W. D. Oliver, Phys. Rev. Lett. 92, 117904 (2004).
[16] Y. Yu, W. D. Oliver, D. Nakada, J. C. Lee, K. K. Berggren, and T. P. Orlando, IEEE Trans. Appl. Supercond. 15, 845 (2005).
[17] R. McDermott, IEEE Trans. Appl. Supercond. 19, 2 (2009).
[18] J. Verjauw et al., Phys. Rev. Appl. 16, 014018 (2021).
[19] A. Anferov, A. Suleymanzade, A. Oriani, J. Simon, and D. I. Schuster, Phys. Rev. Appl. 13, 024056 (2020).
[20] A. Kumar, A. Suleymanzade, M. Stone, L. Taneja, A. Anferov, D. I. Schuster, and J. Simon, Nature 615, 614 (2023).
[21] C.-H. Liu et al., arXiv:2301.05696 (2023).
[22] E. Leonard, Jr. et al., Phys. Rev. Appl. 11, 014009 (2019).
[23] R. McDermott and M. G. Vavilov, Phys. Rev. Appl. 2, 014007 (2014).
[24] R. Zhao, S. Park, T. Zhao, M. Bal, C. R. H. McRae, J. Long, and D. P. Pappas, Phys. Rev. Appl. 14, 064006 (2020).
[25] Y. Nakamura, H. Terai, K. Inomata, T. Yamamoto, W. Qiu, and Z. Wang, Appl. Phys. Lett. 99, 212502 (2011).
[26] Y. Yu, S. Han, X. Chu, S.-I. Chu, and Z. Wang, Science 296, 889 (2002).
[27] S. Kim, H. Terai, T. Yamashita, W. Qiu, T. Fuse, F. Yoshihara, S. Ashhab, K. Inomata, and K. Semba, Commun. Mater. 2, 1 (2021).
[28] L. Grönberg, M. Kiviranta, V. Vesterinen, J. Lehtinen, S. Simbierowicz, J. Luomahaara, M. Prunnila, and J. Hassel, Supercond. Sci. Technol. 30, 125016 (2017).
[29] S. K. Tolpygo, V. Bolkhovsky, T. J. Weir, L. M. Johnson, M. A. Gouker, and W. D. Oliver, IEEE Trans. Appl. Supercond. 25, 1 (2015).
[30] B. Bumble, A. Fung, A. B. Kaul, A. W. Kleinsasser, G. L. Kerber, P. Bunyk, and E. Ladizinsky, IEEE Trans. Appl. Supercond. 19, 226 (2009).
[31] A. I. Braginski, J. Talvacchio, M. A. Janocko, and J. R. Gavaler, J. Appl. Phys. 60, 2058 (1986).
[32] S. K. Tolpygo, D. Amparo, R. T. Hunt, J. A. Vivalda, and D. T. Yohannes, IEEE Trans. Appl. Supercond. 21, 119 (2010).
[33] Exposed with a 375 nm laser.
[34] J. W. Coburn and H. F. Winters, J. Vac. Sci. Technol. 16, 391 (1979).
[35] Transene AlPAD Etch 639.
[36] A. Dunsworth et al., Appl. Phys. Lett. 112, 063502 (2018).
[37] W. Stewart, Appl. Phys. Lett. 12, 277 (1968).
[38] S. Morohashi and S. Hasuo, J. Appl. Phys. 61, 4835 (1987).
[39] S. K. Tolpygo and D. Amparo, Supercond. Sci. Technol. 23, 034024 (2010).
[40] A. A. Golubov, M. Y. Kupriyanov, and E. Il′Ichev, Rev. Mod. Phys. 76, 411 (2004).
[41] V. Ambegaokar and A. Baratoff, Phys. Rev. Lett. 10, 486 (1963).
[42] C. Wen-Hui, Y. Hai-Feng, T. Ye, Y. Hong-Wei, R. Yu-Feng, C. Geng-Hua, and Z. Shi-Ping, Chin. Phys. B 18, 5044 (2009).
[43] H. Sugiyama, A. Fujimaki, and H. Hayakawa, IEEE Trans. Appl. Supercond. 5, 2739 (1995).
[44] A. W. Kleinsasser, R. E. Miller, and W. H. Mallison, IEEE Trans. Appl. Supercond. 5, 26 (1995).
[45] S. Anders, M. Schmelz, L. Fritzsch, R. Stolz, V. Zakosarenko, T. Schönau, and H.-G. Meyer, Supercond. Sci. Technol. 22, 064012 (2009).
[46] K. Senapati, M. G. Blamire, and Z. H. Barber, Appl. Phys. Lett. 97, 162503 (2010).
[47] J. Koch, T. M. Yu, J. Gambetta, A. A. Houck, D. I. Schuster, J. Majer, A. Blais, M. H. Devoret, S. M. Girvin, and R. J. Schoelkopf, Phys. Rev. A 76, 042319 (2007).
[48] R. Barends et al., Phys. Rev. Lett. 111, 080502 (2013).
[49] H. J. Mamin et al., Phys. Rev. Appl. 16, 024023 (2021).
[50] B. Saxberg, A. Vrajitoarea, G. Roberts, M. G. Panetta, J. Simon, and D. I. Schuster, Nature 612, 435 (2022).
[51] A. P. Place et al., Nat. Commun. 12, 1 (2021).
[52] A. Premkumar et al., Commun. Mater. 2, 1 (2021).
[53] C. Wang, C. Axline, Y. Y. Gao, T. Brecht, Y. Chu, L. Frunzio, M. H. Devoret, and R. J. Schoelkopf, Appl. Phys. Lett. 107, 162601 (2015).
[54] D. C. Mattis and J. Bardeen, Phys. Rev. 111, 412 (1958).
[55] S. J. Williamson, Phys. Rev. B 2, 3545 (1970).
[56] A. N. Lykov, Adv. Phys. 42, 263 (1993).
[57] N. G. Connelly and W. E. Geiger, Chem. Rev. 96, 877 (1996).
[58] S. Tasker, R. D. Chambers, and J. P. S. Badyal, J. Phys. Chem. 98, 12442 (1994).
[59] J. H. Thomas III and L. H. Hammer, J. Vac. Sci. Technol. B 5, 1617 (1987).
[60] C. J. Mogab, A. C. Adams, and D. L. Flamm, J. Appl. Phys. 49, 3796 (1978).
[61] L. Stefanazzi et al., Rev. Sci. Instrum. 93, 044709 (2022).
[62] M. S. Khalil, M. J. A. Stoutimore, F. C. Wellstood, and K. D. Osborn, J. Appl. Phys. 111, 054510 (2012).
[63] H. Wang et al., Appl. Phys. Lett. 95, 233508 (2009).

What is claimed is:

1. A Josephson junction, comprising:
a substrate;
a trilayer stack comprising:
a base electrode located directly on a top face of the substrate;
an internal layer located on top of the base electrode;
a barrier layer located on top of the internal layer; and
a counter electrode located on top of the barrier layer and fully covering the barrier layer; and
a wiring layer electrically connected to the counter electrode, the wiring layer comprising:
a top section located directly on top of the counter electrode;
a bottom section located directly on the top face of the substrate and adjacent to the base electrode; and
a middle section directly connecting between the top section and the bottom section such that the middle section forms a gap with the trilayer stack;
wherein no spacer material directly contacts the trilayer stack.

2. The Josephson junction of claim 1, the gap being devoid of solid-state material.

3. The Josephson junction of claim 1, the spacer material comprising silicon oxide.

4. The Josephson junction of claim 1, wherein:
the base electrode comprises a first type of superconducting material;
the internal layer comprises a second type of superconducting material different from the first type of superconducting material; and
the counter electrode comprises the first type of superconducting material.

5. The Josephson junction of claim 4, the first type of superconducting material comprising at least one of: niobium, niobium nitride, titanium nitride, and aluminum.

6. The Josephson junction of claim 4, the second type of superconducting material comprising at least one of: aluminum and niobium nitride.

7. The Josephson junction of claim 1, the barrier layer comprising at least one of: aluminum, aluminum oxide, aluminum nitride, and niobium oxide.

8. The Josephson junction of claim 1, the barrier layer fully covering the internal layer.

9. The Josephson junction of claim 1, the top section of the wiring layer fully covering a top face of the counter electrode.

10. The Josephson junction of claim 1, wherein:
the base electrode is shaped as a rectangular prism having (i) a prism width along a first direction parallel to the top face of the substrate and (ii) a prism length greater than the prism width along a second direction that is parallel to the top face and perpendicular to the first direction;
the counter electrode has a counter-electrode length, along the second direction, that is less than the prism length; and
the wiring layer has a wiring-layer length along the first direction that is greater than the prism width.

11. The Josephson junction of claim 1, wherein the wiring layer comprises:
a first bottom section located directly on the top face of the substrate and adjacent to a first side of the base electrode;
a second bottom section located directly on the top face of the substrate and adjacent to a second side of the base electrode that is opposite to the first side;
a first middle section directly connecting between a first edge of the top section and the first bottom section such that the first middle section forms a first gap with the trilayer stack; and
a second middle section directly connecting between a second edge of the top section, opposite to the first edge, and the second bottom section such that the second middle section forms a second gap with the trilayer stack.

12. The Josephson junction of claim 11, each of the first gap and the second gap being completely devoid of solid-state material.

13. The Josephson junction of claim 1, further comprising a capping layer located between the barrier layer and the counter electrode.

14. The Josephson junction of claim 13, the capping layer having a thickness of 10 nm or less.

15. The Josephson junction of claim 13, wherein;
the capping layer fully covers the barrier layer; and
the counter electrode fully covers the capping layer.

16. The Josephson junction of claim 13, wherein:
the base electrode and the counter electrode comprise niobium;
the internal layer and the capping layer comprise aluminum; and
the barrier layer comprises aluminum oxide.

17. The Josephson junction of claim 1, the substrate comprising sapphire.

18. The Josephson junction of claim 1, having a critical current density less than or equal to 10 kA/cm².

19. The Josephson junction of claim 1, having a junction area less than or equal to 1 μm².

20. The Josephson junction of claim 1, having a coherence time exceeding 16 μs.
